(19) United States
(12) Patent Application Publication
(10) Pub. No.: US 2024/0284631 A1
(43) Pub. Date: Aug. 22, 2024

(54) HOUSING FOR AN ELECTRICAL ASSEMBLY

(71) Applicant: BorgWarner Inc., Auburn Hills, MI (US)

(72) Inventors: Roland BRINKHAUS, Volxheim (DE); Patrick STEINGASS, Alzey (DE)

(21) Appl. No.: 18/442,815

(22) Filed: Feb. 15, 2024

(30) Foreign Application Priority Data
Feb. 20, 2023 (EP) 23157625.7

(51) Int. Cl. H05K 7/20; H05K 5/04

(52) U.S. Cl. CPC H05K 7/20272; H05K 5/04

(57) ABSTRACT

A housing for an electrical assembly with a metallic housing body, which is formed as one part or comprises a plurality of housing parts and which has at least one integrated coolant connection, wherein the coolant connection is formed as a nozzle protruding from the housing body and the coolant connection is formed as one part with the housing body or with one of the housing parts.

### CROSS-REFERENCE TO RELATED APPLICATIONS

This application claims priority pursuant to 35 U.S.C. 119(a) to European Application No. 23157625.7, filed Feb. 20, 2023, which application is incorporated herein by reference in its entirety.

### BACKGROUND OF THE INVENTION

The invention relates to a housing for an electrical assembly.

Electric motors are used in many areas, for example for vehicles, in particular electric cars. However, electric motors are used not only to drive a vehicle, but also in chargers in a vehicle and/or fans for cooling. In a fuel cell for a vehicle, provision can be made for a charger arrangement with an electrically powered or electrically assisted compressor for compressing the air, which increases the efficiency of the system. An electrically powered or assisted charger can also be used in combustion engines.

A housing for electrical assemblies can usually be made of plastic in an injection moulding process in order to prevent any interaction with the electrical components inside the housing. Similarly, the housing can also be produced from a metallic material, for example for shielding.

In the housing of the electric motor, for the cooling of motor components, provision is made for a cooling system in which liquid coolant flows around the components to be cooled in a cooling channel in the housing. These can be rotating or current-carrying components in which heat develops during operation. As an interface for feeding the coolant, coolant connections are provided on the housing through which the coolant flows into and out of the coolant system.

In a conventional housing, the coolant connections are formed as separate connection units which are arranged in recesses in the housing. The connection units can be screwed, pressed, soldered or welded into the housing. There are embodiments in which sealing elements are additionally provided so that the connection between the housing and the connection unit is tight.

### BRIEF SUMMARY OF THE INVENTION

The object is to provide a housing with improved coolant connections.

The housing is provided with a metallic housing body, which is formed as one part or comprises a plurality of housing parts and which has at least one integrated coolant connection, wherein the coolant connection is formed as a nozzle protruding from the housing body and the coolant connection is formed as one part with the housing body or with one of the housing parts.

The housing body is the essential housing part and, as a solid shell, surrounds the components inside the housing body. It protects the components inside the housing. The housing body can be formed as one part or from a plurality of housing parts which are joined together to form the housing body.

The electrical assembly comprises electrical, in particular electronic, components. The assembly is a structural and usually also functional unit of integrated or discrete components which, for example, are electrically and mechanically connected to a support. Examples of an assembly are a control circuit or an electric motor. A further application example is an electrical coolant heater for motor vehicles.

Provision may be made for one or more coolant connections. The coolant feed through which coolant flows to the housing from outside can be connected at the coolant connection. The coolant connection is formed as a nozzle-shaped elevation which is tubular and hollow on the inside in order to guide the coolant in or out. In one embodiment, the nozzle has a hollow-cylindrical basic shape, but it can be widened on transition to the housing body and can, in particular, have external surface structures, for example grooves or ribs. The structures can be formed to enable or facilitate the connection of a coolant feed at the coolant connection.

Instead of using separate connection units as coolant connections and seal as in a conventional housing, the coolant connection is formed integrated with the housing body or the housing part, that is to say that the coolant connection is made as one part with the housing body or the housing part.

The formation of housing body or its housing part and coolant connection as one part reduces the complexity and brings cost advantages. Fewer individual parts are required, in particular no separate connection units and no seals are required for them. There is also no need to keep these components on hand or acquire them for production. The manufacturing step in which these components would have to be joined together with the housing body is therefore also dispensed with. Nor can faults during assembly, such as, for example, connection units not being carefully inserted or fastened into the housing, any longer arise.

Owing to the formation as one part, no additional checking of the coolant interface for tightness is required. The processed housing usually undergoes an overall check for tightness as standard. Through the integration of the coolant connections, the risk of leaks is also reduced, that is to say there is less risk of coolant being able to flow out because there is no connection or interface between the coolant connection and the housing body to be sealed.

A further advantage is that no contact corrosion arises in the coolant connection areas and the neighbouring housing body since, unlike when using conventional separate connection units, different materials of the connection units, the seals and the housing do not come together, as would be possible, for example, in a conventional combination of steel connection units, copper seals and an aluminium housing. The housing body or the housing part and the integrated coolant connection are advantageously made of the same material.

Inside the housing, provision is advantageously made for a cooling system into and out of which liquid coolant, for example water, can be guided through the coolant connections in the housing. At least one cooling channel is provided in the housing body. The cooling channel is a hollow space, which is coupled with the coolant connection so that the coolant can flow through the coolant connection into or out of the cooling channel. Usually, at least two coolant connections are provided per cooling channel, one of which serves as a coolant inlet and the other serves as a coolant outlet for the coolant flowing through the cooling channel.

In one embodiment, the housing body can comprise aluminum or steel so that the housing is stable and light. Magnesium is also a suitable material.

In one embodiment, the one-part housing body or the housing part is formed with the coolant connection as a casting component, for example as a pressure casting component. The coolant connection or an elevation from which the coolant connection is formed through material removal is a cast-on area of the casting component made as one part. Usually, the shape of the coolant connection is formed through further processing from the elevation through material removal. Alternatively, the one-part housing body or the housing part with the coolant connection is formed as a 3D-printing component. In such an embodiment, no further processing to form the coolant connection from an elevation is required.

The further processing of the elevation can advantageously be carried out mechanically, in particular through chip removal. The processing of the elevation can, for example, be carried out through turning or milling using a corresponding tool so that the coolant connection is formed to be stripped or milled through the mechanical processing. The coolant connection is advantageously positioned so that it has tool clearance in order to attach the tool to the elevation from which the coolant connection is then formed. The tool clearance is sufficient space around the coolant connection so that the tool could be attached to make it. There is therefore sufficient distance on the elevation from housing body elevations or further elevations for coolant connections or already formed coolant connections. The tool clearance is advantageously dimensioned for the formation of the coolant connection as a stripped or milled coolant connection.

In one embodiment with a plurality of integrated coolant connections, these are placed on the housing body such that they each have tool clearance for the formation of the coolant connection as a mechanically processed, in particular stripped or milled, coolant connection and, during production, there are no collisions with the housing body or other coolant connections or elevations for coolant connections. A 5-axis station can be used in this production step.

The above-described housing can be provided in an electric motor. In one embodiment, the housing is formed as an axial flow machine housing or as a radial flow machine housing. Such machines can be used in vehicles, for example electric cars. The housing can also be used for electric motors in chargers and/or fans in a vehicle. In such applications, further functional components of the overall arrangement can also be integrated in the housing, for example bearings for a shaft driven by the electric motor, so the housing can in some applications also be referred to as a bearing housing. A charger arrangement with an electrically powered or electrically assisted compressor for compressing air can, for example, be used in conjunction with fuel cells or combustion engines. In such a compressor, the airflow usually flows axially in the compressor.

The housing can alternatively be provided for an actuation device for an electric motor, in particular in a charger device for a fuel cell or a combustion engine. The charger arrangement has a compressor which can be driven electrically and/or by turbines. In a turbine-driven compressor, exhaust gases drive a turbine, the rotation of which is transferred via a shaft to a compressor wheel in the compressor. The turbine-driven compressor can be electrically assisted. Alternatively, the compressor is driven by an electric motor which rotates the compressor wheel. The actuation device comprises an electronic assembly in order to control the operation of the charger device, in particular of the compressor drive. In one embodiment, the actuation device comprises an inverter in order to actuate the operation of the electric motor in the charger device. The housing can be formed integrally with the housing of the charger device or be a separate housing.

In a further embodiment, the housing comprises an electrical coolant heater for motor vehicles. Such a coolant heater can, for example, heat cooling water.

### BRIEF DESCRIPTION OF THE DRAWINGS

A few exemplary embodiments are explained in more detail with reference to the drawing below. In the following:

FIG. 1 shows a schematic three-dimensional view of an exemplary embodiment of an electric motor,

FIG. 2 shows a three-dimensional exploded view of an excerpt of an exemplary embodiment of a conventional housing for an electric motor which does not fall within claim 1, and

FIG. 3 shows a three-dimensional view of an excerpt of an exemplary embodiment of a housing for an electric motor.

### DETAILED DESCRIPTION

In the figures, identical elements or elements carrying out the same function are given the same reference numerals.

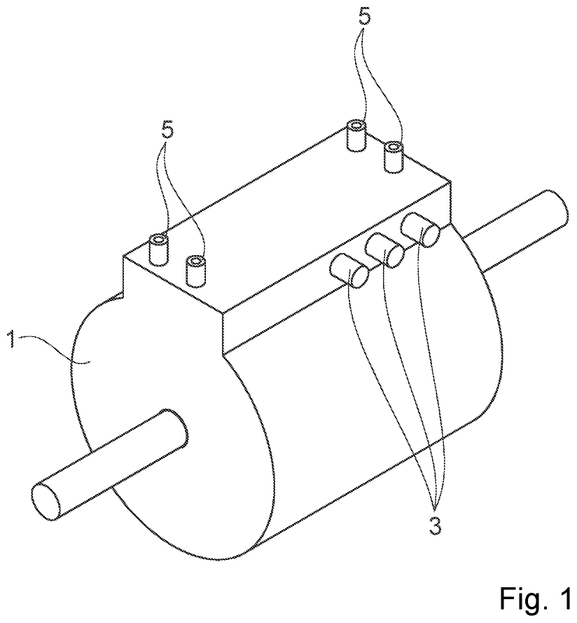

FIG. 1 schematically shows a three-dimensional view of an exemplary embodiment of an electric motor. The housing comprises a housing body 1, connections 3 for supply and control and coolant connections 5 of the cooling system. The housing body 1 is the essential housing part and, as a solid shell and protection, surrounds the components inside the housing body 1 so that they are protected both from the environment and from access. Inside the housing, provision is made for a cooling system into and out of which liquid coolant, for example water, can be guided through the coolant connections 5 in the housing. The housing body 1 can be formed as one part or from a plurality of housing parts, for example with connected front and casing parts. The coolant connections 5 are formed as nozzles protruding from the housing body 1. The coolant connections 5 are made as one part with the housing body 1 or with one of the housing parts.

The electric motor can, for example, be formed as an axial flow machine or radial flow machine. Electric motors are used in many areas, for example for vehicles, in particular electric cars. However, electric motors are used not only to drive a vehicle, but also in chargers and/or fans, for example for cooling, in a vehicle. In a fuel cell for a vehicle, provision can be made for a charger arrangement with an electrically powered or electrically assisted compressor for compressing the air to increase the efficiency of the system. An electrically powered or assisted charger can also be used in combustion engines.

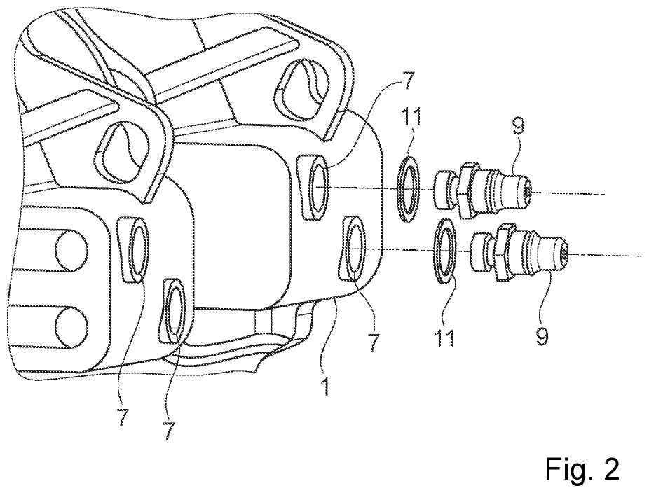

FIG. 2 shows a three-dimensional exploded view of an excerpt of an exemplary embodiment of an electric motor housing with conventional separate coolant connections. On the upper side of the metallic housing body 1 are accesses 7 of the coolant system which are connected to a cooling channel inside the housing body 1. The accesses 7 are formed as openings in the housing body 1. In order to form an interface for the coolant feed which is formed, for example, to be tubular and is not shown in FIG. 1, separate connection units 9 are inserted into the accesses 7. For example, FIG. 1 shows two connection units 9. Further connection units 9 may be provided. An O-ring-shaped seal 11 is provided between each of the connection units 9 and the accesses 7 in the housing body 1. The connection units 9 can be turned or forged. They can be connected to the housing body 1 by screwing or pressing.

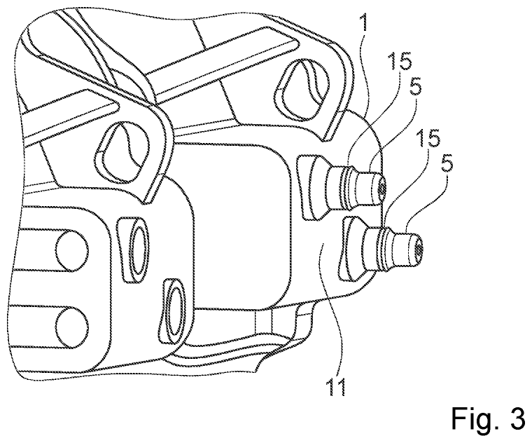

FIG. 3 shows a three-dimensional exploded view of an excerpt of an exemplary embodiment of an electric motor housing with integrated coolant connections 5.

The housing has a metallic housing body 1 which forms the essential part of the housing, which protects and surrounds the functional and rotating components of the electric motor and essentially forms the outside of the electric motor. The housing body 1 can comprise a plurality of housing parts which are joined together. In this case, the housing can still have connection means, for example screws, and seals.

Unlike the previous exemplary embodiment, the coolant connections 5 in this exemplary embodiment are made in one piece with the housing part on which they are arranged, or in one piece with the one-part housing body 1. In one exemplary embodiment, only integrated coolant connections 5 are provided. In an alternative exemplary embodiment, integrated coolant connections 5 and separate connection units 9 can be provided for accesses 7, as indicated in FIG. 3.

The coolant connections 5 protrude as nozzles from the housing body 1 and are formed to be connected to a coolant feed which is not shown in FIG. 3. The nozzles are internally hollow, tubular elevations on the housing body 1. The coolant feed, which is connected to the coolant connection 5, can, for example, be formed to be tubular and guides the liquid coolant to the components of the electric motor inside the housing. The coolant connections 5 are formed as nozzles with a hollow cylindrical basic shape, it being possible for a foot area neighbouring the housing body 1 to be widened in the shape of a cone in an exemplary embodiment. On the outside, provision can be made for encoding and/or retaining means for the coolant feed which are supposed to be attached to the coolant connection 5. Such encodings and/or retaining means can, for example, be notches or ribs or circumferential troughs 15 on the outside.

The coolant connections 5 are made together with the housing part or the housing body 1, resulting in formation as one part already during production. In one exemplary embodiment, the housing part or the housing body 1 is cast or 3D-printed together with the coolant connection 5 in the same step. If provision is made for further processing in order to form the shape of the cooling connections after the housing body 1 or the housing parts have been made, then the housing body 1 or the housing parts are formed together with the elevations provided for coolant connections 5. The coolant connections 5 in their final form are then formed from the elevations which advantageously already have a basic nozzle shape.

The coolant connections 5 or the elevations provided for coolant connections 5 and the housing body 1 or the housing part are made together in the same step, for example by casting or 3D printing. The housing body 1 or the housing part can be formed as a casting, in particular as a pressure casting, in which the coolant connections 5 or the elevations provided for coolant connections 5 are cast. Alternatively, the housing body 1 or the housing part can be formed as a 3D-printing component.

In one embodiment, no provision is made for any further processing of the coolant connections 5 after the above-described production step, this relating in particular to 3D printing and pressure casting. Alternatively, the coolant connections 5 are formed from the elevations provided for the coolant connections 5. The elevations provided for the coolant connections 5 are the basis for the coolant connections 5 and are advantageously already formed to be hollow-cylindrical. Alternatively, the holes in the elevations can also be formed during further processing. The elevations have at least a machining allowance which is removed during the further processing in order advantageously to reduce the production tolerances until the coolant connections 5 have the desired shape. The shape is worked out of the cylindrical elevations according to customer requirements. It is therefore possible to form housing bodies 1 or housing parts with different coolant connections 5 from the same starting bodies.

The coolant connections 5 acquire their final shape through a material-removing production process. In one exemplary embodiment, the coolant connections 5 are stripped. Here, the shape of the coolant connections 5 is formed through chip-removing stripping of elevations provided for coolant connections 5 in the housing body 1. For this purpose, a tool is placed onto the elevations for material removal.

For the further processing, the elevation for the coolant connection 5 and therefore also the coolant connection 5 formed therefrom are positioned such that the elevation or the coolant connection 5 have a tool clearance 13. The tool clearance 13 is an area surrounding the coolant connection 5 in which no housing areas which could hinder the tool protrude in or over. The coolant connection 5 is accessible to the tool for further processing so that, for example, the tool head can be placed on for stripping. If there are a plurality of integrated coolant connections 5, these are placed such that they each have tool clearance 15. The tool for further processing is hindered neither by the shape of the housing body 1 nor by other coolant connections 5 or elevations provided for the coolant connections 5.

In one exemplary embodiment of a housing, provision is made therein for an actuation device for a charger device for a fuel cell or a combustion engine. The charger arrangement has a compressor which can be electrically driven or can have an electrically assisted turbine drive. Such a charger arrangement is also referred to as an e-turbocharger. The actuation device comprises an electronic assembly in order to control the operation of the electric motor for the compressor drive. Advantageously, an inverter is provided in the actuation device in order to control the operation of the electric motor.

In a further exemplary embodiment, the housing comprises an electrical coolant heater for motor vehicles. Such a coolant heater carries out control with an electrical assembly for heating the coolant and actuation thereof can, for example, heat cooling water.

The features above and those that are specified in the claims and can be inferred from the figures can advantageously be realized both individually and in different combinations. The invention is not restricted to the exemplary embodiments described, but can be adapted in many ways within the capability of the person skilled in the art.

### LIST OF REFERENCE NUMERALS

1 Housing body
3 Connection
5 Coolant connection
7 Access
9 Connection unit
11 Seal
13 Tool clearance
15 Troughs

What is claimed is:

1. A housing for an electrical assembly with a metallic housing body, which is formed as one part or comprises a plurality of housing parts and which has at least one integrated coolant connection, wherein the coolant connection is formed as a nozzle protruding from the housing body and the coolant connection is formed as one part with the housing body or with one of the housing parts.

2. The housing according to claim 1, in which at least one coolant channel extends in the housing body, which is coupled with the coolant connection so that a coolant can flow through the coolant connection into or out of the cooling channel.

3. The housing according to claim 1, wherein the one-part housing body or the housing part with the coolant connection is formed as a casting component or as a 3D printing component.

4. The housing according to claim 1, wherein the metallic housing body comprises aluminum, magnesium or steel.

5. The housing according to claim 1, wherein the coolant connection is operated mechanically.

6. The housing according to claim 1, wherein the coolant connection is positioned such that it has tool clearance.

7. The housing according to claim 6, wherein the tool clearance is dimensioned for the formation of the coolant connection as a stripped or milled coolant connection.

8. The housing according to claim 6, which has a plurality of integrated coolant connections which are placed on the housing body such that they each have tool clearance for the formation of the coolant connection as a mechanically operated coolant connection.

9. The housing according to claim 1, which is formed as an axial flow machine housing or as a radial flow machine housing.

10. An electric motor comprising a housing according to claim 1.

11. An actuation device for an electric motor, in particular in a charger device, comprising a housing according to claim 1.

12. The actuation device according to claim 11, which comprises an inverter.

13. An electric coolant heater for motor vehicles comprising a housing according to claim 1.
